(19) United States
(12) Patent Application Publication
(10) Pub. No.: US 2021/0222043 A1
(43) Pub. Date: Jul. 22, 2021

(54) THERMAL MANAGEMENT FOR ELECTRONICS USING NONCONDUCTIVE MAGNETIC PARTICLES

(71) Applicant: SunRay Scientific, Inc., Eatontown, NJ (US)

(72) Inventor: Andrew Stemmermann, Long Branch, NJ (US)

(73) Assignee: SunRay Scientific, Inc., Eatontown, NJ (US)

(21) Appl. No.: 17/155,038

(22) Filed: Jan. 21, 2021

Related U.S. Application Data
(60) Provisional application No. 62/964,092, filed on Jan. 21, 2020.

(51) Int. Cl. C09K 5/14; H01L 23/373; H01L 23/367; H05K 7/20; C09J 9/00; C09J 183/04; C09J 5/06; C09J 7/32; C09J 7/10; F28F 13/18

(52) U.S. Cl. CPC C09K 5/14; H01L 23/3733; H01L 23/3672; H05K 7/2039; C09J 9/00; C09J 183/04; F28F 2013/001; C09J 7/32; C09J 7/10; F28F 13/18; C09J 2203/326; C09J 2483/00; C09J 2301/304; C09J 5/06

(57) ABSTRACT

Compositions for thermal interface materials comprising magnetically-alignable, thermally-conductive, electrically-nonconductive particles in a matrix comprising curable polymers are provided. The compositions are also useful for use as heat sinks. Methods are provided for the use of such compounds for thermal management and heat dissipation in the electronics industry.

### CROSS-REFERENCE TO RELATED APPLICATIONS

This claims benefit of U.S. Provisional Patent Application No. 62/964,092 filed Jan. 21, 2020, the entirety of which is incorporated herein by reference.

### BACKGROUND

### Field of the Invention

This relates generally to novel compositions and methods for thermal management of heat in electronic systems. More particularly, this relates to compositions comprising magnetic particles for use as thermal dissipaters and heat sinks for electronics.

### Description of Related Art

Heat has been described as the “enemy” of electronics. This is understandable in view of the problems associated with unwanted heat build-up such as shortened life/premature failure of components, decreased reliability/increased malfunctions, and safety issues. Excessive heat can necessitate the inclusion of active cooling systems such as forced air or circulating coolants. Heat impacts components, circuit boards, and even solder joints and other interconnections. Of course, heat is inevitable in electronic device because they generate heat in their operation. Because electronic components are generally made of materials that are unable to adequately dissipate enough heat quickly enough to maintain a desirable operating temperature, other strategies are generally required. This is especially true as components like integrated circuits (IC's or chips), whether general purpose microprocessors, application specific ICs, memory chip, or other ICs, get more and more complex. Complex modern ICs can contain billions of transistors. Moreover, modern ICs are being created on a smaller and smaller scale, packed in more and more densely to accommodate the ever-increasing number of elements. Not only do they contain more and more transistors, but they are frequently running faster and faster, creating more heat. Dealing with unwanted heat is an important design and manufacturing consideration some call ‘thermal management.’

Prior art solutions to help with thermal management include the use of forced air systems (e.g. fans), rather than relying on convection of air alone. Great air movement translates directly into great heat dissipation. With earlier generation electronics, a single forced-air low power fan was often sufficient to remove excess heat but as equipment got more complex, heat removal required additional fans. Blockage was always a source of trouble, whether from poor placement, or accumulation of dust, and as boxes got more crowded internally and air movement became more challenging, fans alone were no longer adequate. While fans are still common, thermal management frequently requires multiple fans (including fans attached to key components assemblies to protect them) and multiple approaches used in combination to dissipate sufficient heat build-up.

It will be appreciated that most of the thermal management methods involve removal of heat by transferring to the surrounding fluid, generally air, and therefore the use of ambient air cooling is nearly universal where sensitive electronics are involved and low temperature are not otherwise precluded. Controlled temperature server rooms are the norm, with average temperatures of about 73 F to 75 F. Surprisingly, some experts have concluded that running computing equipment and servers now accounts for the majority of world's electricity consumption—however it is actually the cooling systems for such server rooms that use the largest share of that energy. Accordingly, although servers might perform even better down to e.g. 50 F but the energy requirements for maintaining such temperatures would be cost prohibitive generally.

Other approaches to thermal management include use of liquid cooling systems to cool key internal components. While the use of such coolants provides great capacity to absorb and remove heat, this approach is relatively expensive and not well adapted for large scale production, but custom applications of this method are often used in high-end ‘gaming systems’ and other systems that frequently overheat due to demand). The use of any liquid in proximity to sensitive and expensive electronics, while efficient for heat removal, poses obvious risks in the event of leaks or catastrophic failure.

Passive ‘heat sinks’ to dissipate heat in critical areas are widely employed as methods of thermal management. Based on their thermal properties, such heat sinks preferentially absorb heat away from heat-generating components and release it to a nearby cooling medium (e.g. the air or cooling fluid). They are generally simple mechanical devices attached especially to components (such as CPUs, powered chipsets, high-power semiconductor devices, optoelectronics (e.g. lasers)) that generate the most heat in a system, or used in areas where heat build would be most detrimental to the electronic system involved. They frequently include e.g. cooling fins, and other surface area-maximizing structural features to aid with preferential heat absorption and dissipation. Research is ongoing regarding the use of newer materials such as ceramics, nanomaterials (e.g. carbon nanotubes) with improved thermal properties for heat sinks, or improved designs for cooling fins and related structures to maximize heat dissipation. Ideal solutions will maximize heat dissipation at minimal added costs.

Regardless of what type of heat sink is used, attaching the heat sink to the component generally requires a thermal interface material (“TIM”) between the heat-generating component and the heat sink. Without any TIM, there will be a small but critical gap between the component and the heat sink, which will introduce massive thermal inefficiencies in removing heat. In such a scenario, the component will not be adequately protected.

The use of TIMs to attach passive heat sinks to components is very well established by now but TIMs present problems of their own. They must be simple to apply, must have thermal properties that allow them to increase thermal efficiency of heat transfer from the hot component to the heat sink, they must be cost-effective, and they must not create any electrical interference, shorts, or the like. Unfortunately, most compounds that are great thermal conductors are also good electrical conductors thus the choice of materials well suited as good TIMs is limited.

There is a need for new thermal interface materials for use with passive heat sinks in modern electronics, including microelectronics, as well as new materials for heat sinks.

### SUMMARY

The inventor has surprisingly discovered compositions that are highly useful as thermal interface materials and heat sinks. The compositions generally comprise magnetic particles that are thermally-conductive, and electrically-nonconductive suspended in a polymer or polymer mixture such as a curable resin or epoxy. The particles are on a scale of about 100 nanometers to about 100 micrometers in effective or nominal diameter. The particles generally have a ferromagnetic core that allows them to be manipulated in the presence of a magnetic field but are nonconductive electrically. In various applications, the particles are suspended in a matric comprising e.g. a curable polymer such as an epoxy or resin and applied where needed as thermal interface materials. In the presence of an applied magnetic field, the particles will at least partially align in the direction on the magnetic field (defined as the z-axis herein). Higher-order thermally-conductive structures (e.g. columns or the like) each comprising a plurality of particles will form at least partially in the z-axis but not along the x-y plane.

Thus, the compositions disclosed herein have useful properties with regards to thermal management. They can serve as TIMs to dissipate heat through their unique z-axis structure, and in certain embodiments can serve as a heat sink where needed, with or without any additional or intervening TIM layer. This provides an additional advantage of the present compositions over the prior art TIMs.

In a first of its several aspects, this disclosure provides novel compositions for use as thermal interface material or as heat sinks in the electronic circuitry. The compositions comprise a plurality of thermally-conductive, electrically-nonconductive, magnetically-alignable particles suspended in a matrix comprising an electrically-nonconductive curable polymer. In various embodiments, the matrix comprises an epoxy resin. Preferably the thermal conductivity of the particles (and concomitantly, the higher order structures) is greater than that of the polymer.

In a second aspect of this disclosure, provided herein are heat sinks comprising about 30% to about 80% (w/w) of thermally-conductive, electrically-nonconductive, magnetically-alignable particles suspended in a matrix comprising an electrically-nonconductive curable polymer, and 0.1% to about 40% (w/w) of one or more thermally conductive, electrically-nonconductive fillers.

In certain presently preferred embodiments, the heat sinks (in their cured state) further comprise a plurality of thermally-conductive, electrically-nonconductive structures (e.g. columns and the like). The structures are formed when a magnetic field is applied to the heat sink in its uncured state, i.e. the structures comprise a plurality of particles aligned along the magnetic field lines. These structures are sometimes referred to as ‘columns.’ However, the morphology of the particles disclosed herein may be less uniform than in e.g., certain other applications of ferromagnetic particles that form fairly uniform and clearly discernible columns, thus we have referred to these formations herein more generally as thermally-conductive structures.

In a third aspect, this disclosure provides methods of managing heat dissipation for electrical components. The methods generally comprise the steps:

applying a thermal interface material between the electrical component and a heat sink, wherein the thermal interface material comprises a plurality of thermally-conductive, electrically-nonconductive, magnetically-alignable particles suspended in a matrix comprising an electrically-nonconductive curable polymer;

subjecting the material to a magnetic field thereby causing the particles to align and form thermally-conductive, electrically-nonconductive structures along the magnetic field lines;

initiating the curing of the material by applying heat, or UV light; and

curing the material to produce a thermal interface layer.

The thermally-conductive structures are retained in the cured composition. Preferably, the thermal conductivity of the particles is greater than that of the matrix.

In yet another aspect, this disclosure provides methods of using the compositions disclosed to create heat sinks. The heat sinks can be applied directly to components or across entire substrates. Because the heats sinks so made are nonconductive and yet have excellent thermal conductivity, they can be applied anywhere and everywhere in an electronic system to maximize heat dissipation without risk of creating shorts. In preferred embodiments, the heat sinks can provide ‘microfins’ that substantially increase the surface are of the heat sink and thereby increase the thermal performance of the heat sinks for exchanging heat to e.g. the ambient air.

These and/or further aspects, features, and advantages of the present invention will become apparent to those skilled in the art in view of this disclosure.

### BRIEF DESCRIPTION OF THE DRAWINGS

FIG. 1. depicts an example of a prior art electronic assembly showing a component, and a heat sink, with a thermal interface material layer therebetween.

FIG. 2. depicts an embodiment of the TIMs disclosed herein showing the TIM between a component and a heat sink, with further application across the surface of the substrate.

FIG. 3 depicts an illustration of columns formed within a cured thermal interface material according to this disclosure. As can be seen, the columns have at least some z-axis aspect

FIG. 4 depicts “microfins” formed in an embodiment of a heat sink according the disclosure after exposure to a magnetic field prior to curing.

### DETAILED DESCRIPTION

Provided herein are compositions and methods for improving absorption of fat-soluble nutrients or substances from an edible product or food system.

Definitions & Abbreviations

Unless expressly defined otherwise, all technical and scientific terms, terms of art, and acronyms used herein have the meanings commonly understood by one of ordinary skill in the art in the field(s) of the invention, or in the field(s) where the term is used. In accordance with this description, the following abbreviations and definitions apply.

Abbreviations

The following abbreviations apply unless indicated otherwise:

ACA: anisotropic conductive adhesive;

ACE: anisotropic conductive epoxy;

CPU: central processing unit;

NIB: neodymium, iron, boron

PCB: printed circuit board;

TIM: thermal interface material; and

UV: ultraviolet light of any wavelength.

Definitions

As used herein “substantially” may mean an amount that is larger or smaller than a reference item. Preferably substantially larger (or greater) or smaller (or lesser) means by at least about 10% to about 100% or more than the corresponding reference item. More preferably “substantially” in such instances means at least about 20% to about 100%, or more, larger or smaller than the reference item. As the skilled artisan will appreciate the term ‘substantially’ can also be used as in “substantially all” which mean more than 51%, preferably more than 60%, 67%, 70%, 75%, 80%, 85%, 90%, or more of a referenced item, number, or amount. “Substantially all” can also mean more then 90% including 91, 92, 93, 94, 95, 96, 97, 98, 99 or more percent of the referenced item, number, or amount.

As used herein, the singular form of a word includes the plural, and vice versa, unless the context clearly dictates otherwise. Thus, the references “a”, “an”, and “the” are generally inclusive of the plurals of the respective terms. For example, reference to “an electrode” or “a diode” includes a plurality of such “electrodes” or “diodes”.

The words “comprise”, “comprises”, and “comprising” are to be interpreted inclusively rather than exclusively. Likewise, the terms “include”, “including” and “or” should all be construed to be inclusive, unless such a construction is clearly prohibited from the context. Further, forms of the terms “comprising” or “including” are intended to include embodiments encompassed by the phrases “consisting essentially of” and “consisting of”. Similarly, the phrase “consisting essentially of” is intended to include embodiments encompassed by the phrase “consisting of”.

Where used herein, ranges are provided in shorthand, so as to avoid having to list and describe each and every value within the range. Any appropriate value within the range can be selected, where appropriate, as the upper value, lower value, or the terminus of the range.

The formulations, compositions, methods and/or other advances disclosed here are not limited to particular methodology, protocols, and/or components described herein because, as the skilled artisan will appreciate, they may vary. Further, the terminology used herein is for the purpose of describing particular embodiments only, and is not intended to, and does not, limit the scope of that which is disclosed or claimed.

Although any formulations, compositions, methods, or other means or materials similar or equivalent to those described herein can be used in the practice of the present invention, the preferred formulations, compositions, methods, or other means or materials are described herein.

Any references, including any patents, patent applications, or other publications, technical and/or scholarly articles cited or referred to herein are in their entirety incorporated herein by reference to the extent permitted under applicable law. Any discussion of those references is intended merely to summarize the assertions made therein. No admission is made that any such patents, patent applications, publications or references are prior art, or that any portion thereof is either relevant or material to the patentability of what is claimed herein. Applicant specifically reserves the right to challenge the accuracy and pertinence of any assertion that such patents, patent applications, publications, and other references are prior art, or are relevant, and/or material.

As used herein, “alignment” means aligning a magnetic material or composition comprising magnetic particles. Generally, aligning refers to the arrangement of magnetic particles in the z-axis under the influence of a magnetic field. Alignment is the process by which columns are formed in the z-axis. As will be clear from the context, sometimes ‘alignment’ is also used herein to refer to ensuring the proper orientation of two things with respect to each other.

As used herein, “columns” refers to the structures formed by magnetic particles in a composition in the z-axis under the influence of a magnetic field. The process of column formation is sometimes referred to as ‘alignment’. The column properties (e.g. height, diameter, etc.) will be determined by the strength of the magnets and the properties of the ACA or ACE including the size and amount of the magnetic particles in the ACA, and the viscosity and other physical properties of the ACA or ACE matrix. Columns can and will form within seconds of exposure to a suitable magnetic field.

A “magnet” is capable of producing a “magnetic field” which as used herein includes any magnetic field whether produced by an electromagnet or a permanent magnet. The “strength” of a magnet can be measured in Gs (or Ts).

As used herein, a “permanent magnet” means a magnet that does not require electrical current to flow in order to have a persistent magnetic field. Permanent magnets for use herein can comprise iron, nickel, cobalt, and rare earth metals. Certain presently preferred embodiments herein utilize rare earth magnets such as those comprising lanthanoid elements. Magnets comprising neodymium, or salts thereof, may be useful herein because of their magnetic strength. In one embodiment, the magnets comprise neodymium, iron, and boron (“NIB magnets”). Samarium, gadolinium, and even dysprosium, and salts thereof may be used for specific applications. Other types of permanent magnets such as ceramic magnets and other composite magnets, and even flexible magnets may be suitable for use herein for other specific applications.

As used herein, a “coating” is generally any outer layer, covering, skin, or the like, regardless of its structure or how it is applied or achieved, that alters or masks one or more physical properties of the underlying material on which the coating resides, while not substantially altering other physical properties of the underlying material. For example, a nonconductive material may be used to cover, coat, encapsulate, or the like, an electrically conductive material such as a ferromagnetic core. In preferred embodiments herein the final particles comprising the electrically-conductive core and the nonconductive outer coating are electrically-nonconductive, yet retain excellent thermal conductivity.

As used herein “curing” means polymerizing a resin or similar polymer matrix. Curing may comprise the use of heat and/or UV light. Curing can generally be initiated or sped up by the use of various catalysts. The skilled artisan will appreciate the appropriate catalysts to use with thermal- or UV-curing. It is understood that for thermal interface materials to be UV-curable, the system must provide means for UV light to reach the curable material. Thus, if there is no way for the TIM to be exposed adequately to UV light, then UV curing will not be useful. Accordingly, UV transparent components, substrates, or the like may be required for such applications.

As used herein “UV light” e.g. for purposes of UV curing, means any wavelength of light in the UV range, from about 240 nm to about 360 nm. If a particular commercial UV catalyst or curing process is used, the manufacturer will provide detailed instructions on preferred wavelengths.

As used herein “conductivity” means the ability of a material to conduct electric current or heat. In either case the reciprocal property is ‘resistivity.’ The skilled artisan will appreciate that in general many good thermal conductors are good electrical conductors and vice versa. For purposes of this disclosure, preferred particles are generally good thermal conductors and poor electrical conductors. Or stated differently, preferred particles have good electrical resistance, and also are good thermal conductors. For purposes herein, “electrically nonconductive” is shorthand for “substantially nonconductive” or “relatively nonconductive”, and does not mean “absolutely nonconductive” in any strict sense. Materials that are sufficiently nonconductive for purposes herein will not cause shorts when used in electrical system. Preferred for use herein (e.g. for coatings) are materials that are poor electrical conductors, i.e. material which have high resistivity.

As used herein a “substrate” is any material used to hold or contain and other electronic components connected thereon for use in an electronic system or device, such as a printed circuit board (‘PCB’). Substrates can be flexible or rigid. Preferred rigid substrates include e.g. PCBs, composites, and rigid polymers, and preferred flexible supports include e.g., flexible polymers.

As used herein, “z-axis” means the direction that is perpendicular to the main plane in which the substrate lies, i.e. the x-y plane.

Detailed Description of Illustrative Embodiments

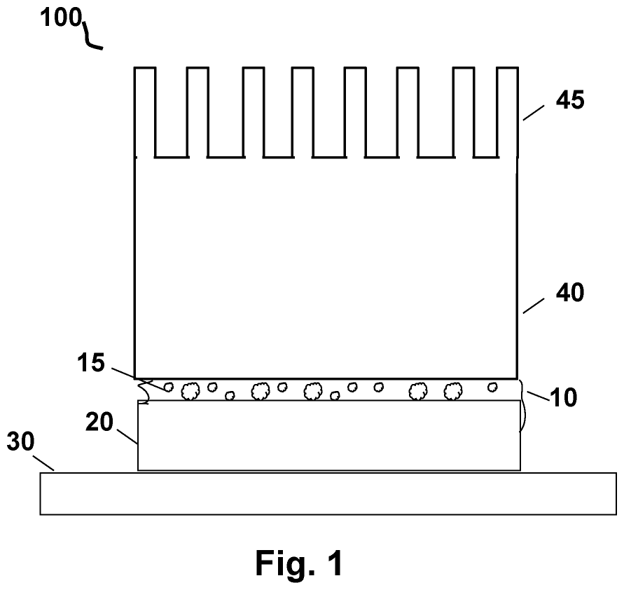

The inventor has discovered unexpected improvements in thermal management using the compositions disclosed herein. Compositions for use as improved thermal interface materials are provide. The compositions are also useful for creating heat sinks that can directly thermally connected to substrates of components where thermal management is required to prospectively address, e.g., excessive heat buildup. Unlike prior art approaches, the compositions disclosed herein provide distinct advantages. A general example of a prior art thermal interface material in use is depicted in FIG. 1. A thermal paste 10 comprising thermal conductors 15 comprising silver, aluminum, or the like is provided. Thermal paste 10 is shown in the interface between heat-generating component 20 on substrate 30 and heat sink 40, having heat dissipation fins 45. The thermal paste 10 must be carefully applied as it contains conductive metal fillers that can potentially create shorts in the system 100 of which component 20 and substrate 30 are a part. That risk necessitates carefully applying the prior art thermal paste 10 to avoid such shorts, Mitigating that risk increases the time and expense of using thermal paste 10 as a TIM. In addition, the thermal conductors 15 in thermal paste 10 can be costly.

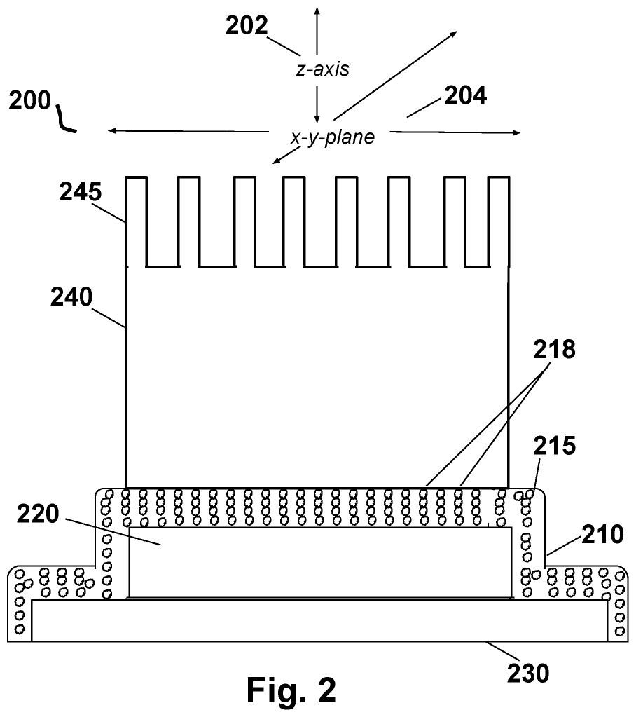

The compositions disclosed herein comprise magnetically-alignable particles, ferromagnetic particles, to help provide structures to promote efficient removal of heat from the source. Unlike applications of magnetically-alignable particles for use as anisotropic conductive adhesives (ACAs) or anisotropic conductive epoxies (ACEs) such as those available from SunRay Scientific, LLC, the compositions disclosed herein provide that the particles are substantially nonconductive, thus eliminating the risk of shorts discussed above. Another distinction is that the column formation need not be exclusively along the z-axis as with ACAs and ACEs, but rather the structures herein need only have a component of z-axis, i.e. structures will suffice provided they are not solely in the x-y plane (see FIG. 2).

The column formation that is at least partially, if not largely or even entirely in the z-axis as a result of briefly exposing the magnetically-alignable particles in the compositions to a magnetic field assures that heat is transferred most efficiently along the z-axis where it can be dissipated into a medium on the opposite side of the substrate or component to which it is attached. When the compositions are used as thermal interface material between a component and a heat sink thereon, the heat can be transferred directly to the heat sink. Moreover, the nonconductive nature of the particles and the matric base eliminates the risk of shorting and allows more flexibility in application of the compositions to the electronic circuitry, components, substrates and the like.

As can be seen in FIG. 2, the thermal interface material can be safely and conveniently applied over a larger area including the component 220 and portions or even the entirety of substrate 230. Structures 218 are thermally-conductive, column-like structures that formed by a plurality of thermal conductor along magnetic field lines 250 with at least some degree of z-axis 202 (i.e. across the span of the TIM 210). As shown, the structures 218 can be more or less perpendicular to the x-y plane and parallel to each other. However, as can be seen even under the most spread magnetic field as shown, the attractive forces ensure that no structures 210 form solely along/parallel to the x-y plane 204. No prior TIM has had this property, which provides superior heat transfer in the desired direction.

A first aspect of the disclosure thus provides compositions for use as a thermal interface material or a heat sink in electronic circuitry. The compositions comprise a plurality of thermally-conductive, electrically-nonconductive, magnetically-alignable particles suspended in a matrix comprising an electrically-nonconductive curable polymer. Preferably, the thermal conductivity of the particles is greater than that of the matrix. The skilled artisan will appreciate that in the presence of an applied magnetic field, the particles in the uncured composition align to form thermally-conductive, electrically-nonconductive structures along the magnetic field lines. Those thermally-conductive structures are retained in the cured composition.

In various embodiments, the particles comprise nickel, iron, cobalt, ferromagnetic rare earth elements. In other embodiments the particles comprise combinations of those, or ferromagnetic alloys of them. In yet other embodiments, the particles comprise hematite, ferrite, or magnetite.

In presently preferred embodiments the particles comprise iron-nickel (e.g. FeNi), iron-nickel-cobalt (e.g. FeCoNi), or ferromagnetic alloys of iron with carbon or chromium.

In one embodiment the particles comprise a ferromagnetic core coated with a non-conductive coating such that the particles are substantially electrically-non-conductive. As described above, it is very useful for the particles to be nonconductive electrically, to avoid the risk of shorting and allow more liberal conditions for applying the TIM to a substrate or a to a component.

In various embodiments, the particles have a resistivity equal to or greater than about 10⁸ Ω·cm in the relevant temperature range. In various embodiments, such materials have resistivity of at least about 10⁷ Ω·cm to about 10⁸ Ω·cm. Preferred materials may have resistivity of about 10⁸ Ω·cm to about 10¹⁰ Ω·cm. More preferred are materials with resistivity of about 10¹⁰ Ω·cm to about 10¹² Ω·cm, about 10¹² Ω·cm to about 10¹⁵ Ω·cm, and about 10¹⁵ Ω·cm to about 10¹⁸ Ω·cm or greater.

The coating can comprise any electrically nonconductive coating that can be applied to the particles. Thus, the coating in various embodiments is a nonconductive oxide, nitride, sulfide, plastic, polymer, glass, clay, ceramic, quartz, fused silica, diamond, hematite, or magnetite. In one embodiment the coating comprises NiO, SiO₂, or Si₃N₄.

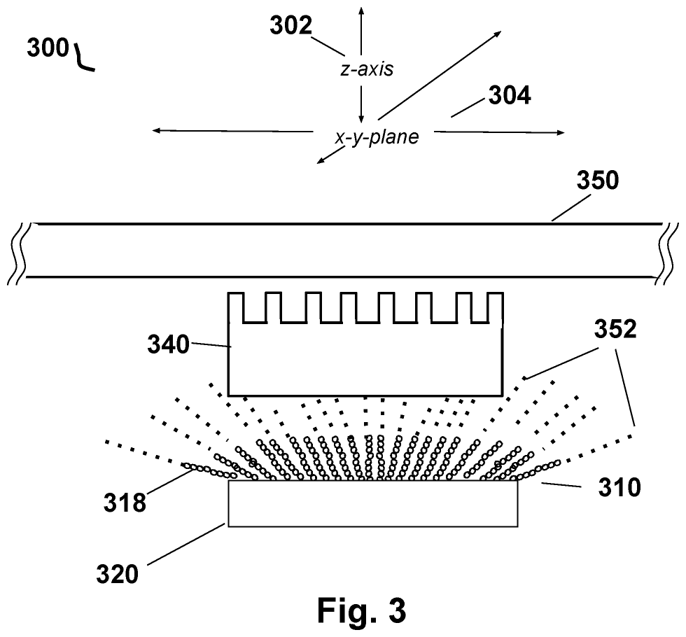

The magnetically-alignable particles can form or assemble into higher-order structures as shown in FIG. 2. Such structures form in a TIM 310 in the interface between component 320 and the heat sink 340 along magnetic field lines as shown in FIG. 3 (note the substrate is not shown). With reference to FIG. 3, structures 318 form along magnetic field lines 352 created by magnet 350 with at least some degree of z-axis 302 (i.e. across the thickness of the TIM 310) direction. Depending on the nature of the magnet 350 and the resultant magnetic field 352 applied, the structures 318 can be more or less perpendicular to the x-y plane 304 and parallel to each other (as exemplified in FIG. 2). However, as can be seen, even under the most spread magnetic field 352 as shown, the attractive forces ensure that no structures 318 form solely along/parallel to the x-y plane 304. No prior art TIM or heat sink has provided this feature, which allows for superior heat transfer in the desired direction.

The nominal size of the particles ranges from about 50 nanometers to about 100 microns.

The nominal size of the particles can be selected based on thickness of an interface layer, by determining the approximate minimum number of particles that are desired per column and then back calculating to determine the average diameter.

In various embodiments, the average nominal size of the particles is less than about 1 micron. In other embodiments, the average nominal size of the particles is about 0.3 microns.

In other cases, a range a particle sizes may be useful, for example, the average nominal size of the particles ranges from about 10 microns to less than about 100 microns, or from or from, or from, or from,.

The particles can have any useful morphology or shape in whole or part. Because the application to thermal conductance is less rigorous than electrical conductance where the risk of shorting is ever present, more options are possible. In various embodiments herein, the morphology of the particles is at least partially spheres, flakes, crystals, rods, dendrites, or urchins. In other cases, there is a mixture of morphologies, or the particles are largely amorphous.

In presently preferred embodiments, the matrix comprises an adhesive, such as an epoxy-type curable resin. The curable polymer can be cured thermally or via exposure to UV light.

The matrix comprises silicone, solvent-based polymer, or solvent-free polymer in various embodiments.

The composition prior to curing can be any state of matter that is convenient or useful for a particular application including a liquid, a semisolid, a gel, a paste, or a film. The composition can be partially cured in certain applications.

The composition is preferably applied e.g., dispensed, sprayed, stenciled, screened, or 3-D printed, onto a substrate or component.

In one embodiment, the composition further comprises one or more additional thermally-conductive, electrically-nonconductive fillers. The fillers increase the net heat dissipation of the composition under conditions of use. The additional thermally-conductive fillers can comprise any thermally conductive, electrically nonconductive material suitable for adding such as aluminum nitride, aluminum oxide, boron nitride, or beryllia, silica, or quartz.

The compositions generally have at least about 10% by weight of the particles to about 80% by weight of the particles. Compositions are most useful as a thermal interface material when they comprise about 20% to about 50% (w/w) particles. For use as a heat sink the composition may be more heavily loaded with particles, preferably having about 40% to about 80% (w/w) particles.

In a second aspect of the disclosure heat sinks are provided. The heat sinks generally comprise about 30% to about 80% of thermally-conductive, electrically-nonconductive, magnetically-alignable particles. The particles are suspended in a matrix comprising an electrically-nonconductive curable polymer. Preferably about 0.1% to about 40% (w/w) of one or more thermally conductive, electrically-nonconductive fillers are also present.

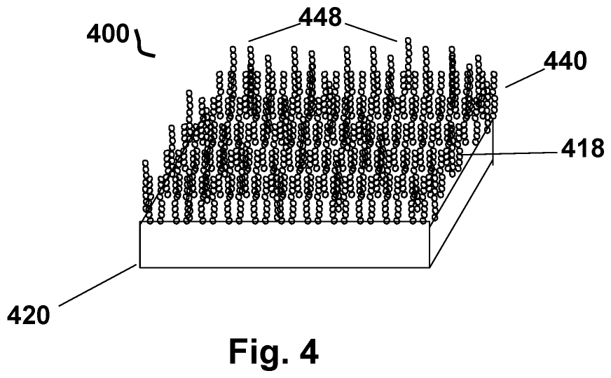

It is not critical for heat sinks to contain the z-axis structures because of the generally heavier load of particles. Accordingly, they need not be exposed to a magnetic field prior to curing. Nonetheless, in some embodiments such as that depicted in FIG. 4 (described below), a plurality of thermally-conductive, electrically-nonconductive structures are present in the cured state, formed in response to a magnetic field applied to the heat sink in an uncured state. These thermo-conductive structures comprise particles aligned along the magnetic field lines.

The structures form “microfins” or small columns that protrude at the upper surface of the heat sink. These microfins increases the effective surface of the heat sink and thereby increase the heat dissipation of the heat sink. Thus, use of the magnet prior to curing is useful for the formation of these microfins and for improving the heat dissipation and performance of the sink in certain embodiments.

Without limiting the invention to any one theory of operation, it appears that the number and length of the microfins may be a function of several factors including the particle content of the heat sink, the viscosity of the uncured matrix, the temperature of the curing, and of the strength of the magnetic field applied in the uncured state.

With reference to the FIGS. an embodiment of a heat sink according to the disclosure can be seen in FIG. 4. As can be seen the heat sink 440 provides the novel feature of being directly applicable to e.g. a component 420. In other words, no additional interface between the heat sink 440 and the component 420 is needed, i.e. no TIM is required. A large number of structures 418 are preferably formed in the body of the heat sink 440. However, at various intervals throughout the heat sink 440, structures 418 are seen with intervening microfins 448. The microfins are very small and very numerous and accordingly greatly increase the effective surface area of the heat sinks provided herein and allow for surprising efficient heat dissipation as compare to traditional or prior art sinks.

The particles in the heat sinks disclosed herein comprise one or more of nickel, iron, cobalt, ferromagnetic rare earth elements, combinations or ferromagnetic alloys of any of the foregoing, hematite, ferrite, or magnetite. In certain embodiments, the particles comprise FeNi, FeCoNi, or ferromagnetic alloys of iron with carbon or chromium.

The particles, like those in the first aspect of this disclosure generally comprise a ferromagnetic core coated with a non-conductive coating such that the particles are substantially electrically-non-conductive. Preferably the particles of the heat sinks have a resistivity equal to or greater than about 10⁸ Ω·cm in the relevant temperature range, and excellent thermal conductivity, or at least they do not substantially interfere with the thermal conductivity of the particles they coat.

The coating in various embodiments comprises an electrically nonconductive oxide, nitride, sulfide, plastic, polymer, glass, clay, ceramic, quartz, fused silica, diamond, hematite, or magnetite. The coating can comprise NiO, SiO₂, or Si₃N₄ in certain embodiments.

As with the prior aspect described above, the nominal size of the particles ranges from about 50 nanometers to about 100 microns, and have a morphology that is at least partially spheres, flakes, crystals, rods, dendrites, or urchins, or is amorphous.

As described above, heat sinks preferably include thermal fillers to increase the net heat capacity/absorption and dissipation of the composition under conditions of use.

The matrix comprises an adhesive preferably, such as an epoxy. The curable polymer can be cured thermally or via exposure to UV light. The matrix in various embodiments comprises silicone, solvent-based polymer, or solvent-free polymer. Solvent-free polymers may be particular useful in the field of medical devices, such as implantables. For heat sinks, the matrix is preferably a viscous liquid, or a semisolid in the uncured state.

In a third aspect of the invention, provided herein are methods of managing thermal properties of at least one electrical component. The methods generally comprise the steps of:

applying a thermal interface material between the electrical component and a heat sink, wherein the thermal interface material comprises a plurality of thermally-conductive, electrically-nonconductive, magnetically-alignable particles suspended in a matrix comprising an electrically-nonconductive curable polymer;

subjecting the material to a magnetic field thereby causing the particles to align and form thermally-conductive, electrically-nonconductive structures along the magnetic field lines;

initiating the curing of the material by applying heat, or UV light; and

curing the material to produce a thermal interface layer;

wherein the thermally conductive structures are retained in the cured composition, and

wherein the thermal conductivity of the particles is greater than that of the matrix.

In various embodiments, the thermal interface material is a liquid, a semisolid, a gel, a paste, or a film, and the applying step comprises dispensing, coating, spraying, stenciling, dipping, depositing, 3D-printing, or covering with a film.

Preferably and advantageously, the applying step does not require added pressure.

The thermal interface material does not include any organic solvent in certain embodiments. Also advantageous is that the applying step is not limited to a planar area of an electronic assembly. In some embodiments, the applying step involves covering an entire electronic assembly or substrate with multiple components rather than just an area between a component and a heat sink.

With use of the inventor's compositions disclosed herein, the applying step does not pose any risk of creating shorts in the electronic assembly.

The curing step in one embodiment is thermal and the temperature does not exceed 200 C. In other embodiments, the curing temperature need not exceed 150 C, 120 C, or even 100 C.

The scope of the invention is set forth in the claims appended hereto, subject, for example, to the limits of language. Although specific terms are employed to describe the invention, those terms are used in a generic and descriptive sense and not for purposes of limitation. Moreover, while certain presently preferred embodiments of the claimed invention have been described herein, those skilled in the art will appreciate that such embodiments are provided by way of example only. In view of the teachings provided herein, certain variations, modifications, and substitutions will occur to those skilled in the art. It is therefore to be understood that the invention may be practiced otherwise than as specifically described, and such ways of practicing the invention are either within the scope of the claims, or equivalent to that which is claimed, and do not depart from the scope and spirit of the invention as claimed.

What is claimed is:

1. A composition for use as a thermal interface material or a heat sink in electronic circuitry, said composition comprising a plurality of thermally-conductive, electrically-nonconductive, magnetically-alignable particles suspended in a matrix comprising an electrically-nonconductive curable polymer, wherein the thermal conductivity of the particles is greater than that of the matrix, wherein in the presence of an applied magnetic field, the particles in the uncured composition align to form thermally-conductive, electrically-nonconductive structures along the magnetic field lines which structures are retained in the cured composition.

2. The composition of claim 1 wherein the particles comprise one or more of nickel, iron, cobalt, ferromagnetic rare earth elements, combinations or ferromagnetic alloys of any of the foregoing, hematite, ferrite, or magnetite.

3. The composition of claim 2 wherein the particles comprise FeNi, FeCoNi, or ferromagnetic alloys of iron with carbon or chromium.

4. The composition of claim 1 wherein the particles comprise a ferromagnetic core coated with a non-conductive coating such that the particles are substantially electrically-non-conductive.

5. The composition of claim 4 wherein the particles have a resistivity equal to or greater than about 10⁸ Ω·cm in the relevant temperature range.

6. The composition of claim 2 wherein the coating comprises an electrically nonconductive oxide, nitride, sulfide, plastic, polymer, glass, clay, ceramic, quartz, fused silica, diamond, hematite, or magnetite.

7. The composition of claim 6 wherein the coating comprises NiO, SiO₂, or Si₃N₄.

8. The composition of claim 2 wherein the average nominal size of the particles ranges from about 10 microns to less than about 100 microns.

9. The composition of claim 2 wherein the particles have a morphology that is at least partially spheres, flakes, crystals, rods, dendrites, or urchins, or is amorphous.

10. The composition of claim 1 wherein the matrix comprises an adhesive comprising silicone, solvent-based polymer, or solvent-free polymer.

11. The composition of claim 1 further comprising one or more additional thermally-conductive, electrically-nonconductive fillers which increase the net heat dissipation of the composition under conditions of use.

12. The composition of claim 1 comprising at least about 10% by weight of the particles to about 80% by weight of the particles.

13. A heat sink comprising about 30% to about 80% of thermally-conductive, electrically-nonconductive, magnetically-alignable particles suspended in a matrix comprising an electrically-nonconductive curable polymer, and 0.1% to about 40% (w/w) of one or more thermally conductive, electrically-nonconductive fillers.

14. The heat sink of claim 13 further comprising a plurality of thermally-conductive, electrically-nonconductive structures in a cured state, said structures formed in response to a magnetic field applied to the heat sink in an uncured state, wherein the structures comprise particles aligned along the magnetic field lines.

15. The heat sink of claim 14 wherein the structures form microfins at the upper surface of the heat sink, wherein the microfins increases the effective surface of the heat sink and thereby increase the heat dissipation of the heat sink.

16. The heat sink of claim 13 wherein the particles comprise a ferromagnetic core coated with a non-conductive coating such that the particles are substantially electrically-non-conductive.

17. The heat sink of claim 13 wherein the particles have a resistivity equal to or greater than about 10⁸ Ω·cm in the relevant temperature range.

18. The heat sink of claim 13 wherein the fillers increase the net heat dissipation of the composition under conditions of use and comprise aluminum nitride, aluminum oxide, boron nitride, or beryllia, silica, or quartz.

19. A method of managing thermal properties of at least one electrical component comprising:
applying a thermal interface material between the electrical component and a heat sink, wherein the thermal interface material comprises a plurality of thermally-conductive, electrically-nonconductive, magnetically-alignable particles suspended in a matrix comprising an electrically-nonconductive curable polymer;
subjecting the material to a magnetic field thereby causing the particles to align and form thermally-conductive, electrically-nonconductive structures along the magnetic field lines;
initiating the curing of the material by applying heat, or UV light; and
curing the material to produce a thermal interface layer;
wherein the thermally conductive structures are retained in the cured composition, and
wherein the thermal conductivity of the particles is greater than that of the matrix.

20. The method of claim 20 wherein the thermal interface material is a liquid, a semisolid, a gel, a paste, or a film, and the applying step comprises dispensing, coating, spraying, stenciling, dipping, depositing, 3D-printing, or covering with a film.
